(19) United States
(12) Patent Application Publication
(10) Pub. No.: US 2024/0352573 A1
(43) Pub. Date: Oct. 24, 2024

(54) SURFACE PREPARATION FOR JVD

(71) Applicant: ArcelorMittal, Luxembourg (LU)

(72) Inventors: Daniel CHALEIX, Verny (FR); Véronique HEBERT, Saint Julien-les-Metz (FR); Fabrice LAFFINEUR, Ville-en-Hesbaye (BE); Vincent RUWET, Visé (BE)

(21) Appl. No.: 18/701,735

(22) PCT Filed: Sep. 5, 2022
(86) PCT No.: PCT/IB2022/058327

§ 371 Date: Apr. 16, 2024

(30) Foreign Application Priority Data
Oct. 19, 2021 (WO) PCT/IB2021/059600

(51) Int. Cl. C23C 14/24; C21D 1/76; C21D 6/00; C21D 8/02; C21D 9/46; C22C 38/02; C22C 38/06; C22C 38/38; C23C 14/16

(52) U.S. Cl. CPC C23C 14/24; C21D 1/76; C21D 6/002; C21D 6/005; C21D 6/008; C21D 8/0205; C21D 8/0221; C21D 8/0247; C21D 9/46; C22C 38/02; C22C 38/06; C22C 38/38; C23C 14/16; C21D 2211/001; C21D 2211/002; C21D 2211/005; C21D 2211/008

(57) ABSTRACT

A method for depositing metallic coatings on a substrate including an annealing step, in an annealing furnace, forming on said substrate, a ferritic surface layer having a thickness from 10 μm to 50 μm and a microstructure comprising in surface fraction up to 10% of cumulated amount of martensite, bainite and the balance being made of ferrite, a skin pass step, a coating step, inside a vacuum chamber, wherein a metallic vapour is ejected towards at least a side of said substrate to form a surface layer of at least one metal.

The present invention relates to a method for depositing metallic coatings on a substrate. This invention also relates to a coated steel strip.

### BACKGROUND

The invention is particularly intended for depositing an anti-corrosion metallic coating, such as a zinc or zinc-magnesium based coating, onto a running steel strip without being limited thereto. Such a coated steel strip can then be cut and shaped, for example by stamping, bending or shaping, to form a part that can then be painted in order to form a paint film on top of the coating.

Several coating methods exist such as hot-dip coating and electrocoating. However, these conventional methods do not provide a satisfying coating for steel grades containing high level of oxidizable elements such as Si, Mn, Al, P, Cr or B. Consequently, new methods have been developed e.g. vacuum deposition technologies such as JVD (Jet Vapour Deposition).

In JVD, a metallic vapor spray, propelled at a supersonic speed, comes into contact with a substrate in a vacuum chamber as described in WO97/47782 and WO2009/047333.

### SUMMARY OF THE INVENTION

Nevertheless, it has been observed that such processes lead sometimes to coating deterioration, especially during the shaping process. The aim of the present invention is to remedy this drawback.

The present invention provides a method for depositing metallic coatings on a steel substrate comprising:
i. an annealing step, in an annealing furnace, comprising
   a. a pre-heating wherein said steel substrate is heated to a temperature T1 lower than 600° C.
   b. a heating step wherein said substrate is heated from T1 to a recrystallisation temperature T2 from 720° C. to 1000° C. in an atmosphere comprising 0.1 to 90% by volume of H₂, the balance being an inert gas and unavoidable impurities and having a dew point from −25° C. to 10° C. and then
   C. a soaking step wherein said substrate is maintained in a temperature range from 720° C. to 1000° C. in an atmosphere comprising 0.1 to 90% by volume of H₂, the balance being an inert gas and unavoidable impurities and having a dew point from −25° C. to 10° C., wherein such an annealing step allows to form, on said substrate, a ferritic surface layer having a thickness from 10 μm to 50 μm and a microstructure comprising in surface fraction up to 10% of cumulated amounts of martensite, austenite, bainite and carbide, and the balance being made of ferrite,
ii. a skin pass step, at a temper mill, wherein said substrate is rolled with a reduction from 0.02% to 2%,
iii. a coating step, inside a vacuum chamber, wherein at least a metallic vapour is ejected towards at least a side of said substrate to form a metallic coating.

Other characteristics and advantages will become apparent from the following detailed description of the invention.

### BRIEF DESCRIPTION OF THE DRAWINGS

To illustrate the invention, various embodiment will be described, particularly with reference to the following figures:

FIG. 1 embodies the steel substrate layers after the annealing step according to the invention.

FIG. 2 embodies the steel substrate layer after the coating step according to the invention.

FIG. 3 embodies the different steps of a 3-steps flanging test.

### DETAILED DESCRIPTION

The invention relates to a method for depositing metallic coatings on a steel substrate comprising:
i. an annealing step, in an annealing furnace, comprising
   a. a pre-heating wherein said steel substrate is heated to a temperature T1 lower than 600° C.,
   b. a heating step wherein said steel substrate is heated from T1 to a recrystallisation temperature T2, from 720° C. to 1000° C., in an atmosphere comprising 0.1 to 90% by volume of H₂, the balance being an inert gas and unavoidable impurities and having a dew point from −25° C. to 10° C.,
   C. a soaking step wherein said steel substrate is maintained in a temperature range from 720° C. to 1000° C. in an atmosphere comprising 0.1 to 90% by volume of H₂, the balance being an inert gas and unavoidable impurities and having a dew point from −25° C. to 10° C.,
   wherein such an annealing step allows to form, on said steel substrate, a ferritic surface layer having a thickness from 10 μm to 50 μm and a microstructure comprising in surface fraction up to 10% of cumulated amounts of martensite, austenite, bainite and carbide, and the balance being made of ferrite,
ii. a skin pass step, at a temper mill, wherein said steel substrate is rolled with a reduction rate up from 0.02% to 2%,
iii. a coating step, inside a vacuum chamber, wherein at least a metallic vapour is ejected towards at least a side of said substrate to form a metallic coating.

Prior to the annealing step, the steel substrate can be rolled. For example, the substrate is preferably subjected to a hot rolling and then to a cold rolling.

Preferably, the method relates to a method for depositing metallic coatings on a steel running substrate. Preferably, in the coating step, said at least metallic vapour is ejected towards at least a side of said steel running substrate

Preferably, said annealing step is performed in a continuous annealing furnace.

During the pre-heating, the steel sheet is usually heated from room temperature to a temperature T1 lower than 600° C. The pre-heating can be done by any means. For example, the pre-heating can be done in a RTF (Radiant Tube Furnace), by means of an induction device or in a DFF (Direct-Fired Furnace).

Limiting the pre-heating temperature to lower than 600° C. is advantageous because it reduces the oxidation on the steel sheet. Preferably, T1 is lower than 550° C. Even more preferably, T1 is lower than 500° C.

Preferably, in the heating step, the dew point is from −20° C. to −1° C. Preferably, in the soaking step, the dew point is from −20° C. to −1° C.

The atmospheres in the heating step and in the soaking step can be achieved by using preheated steam and incorporating N₂—H₂ gases in a furnace equipped with H₂ detectors in the different sections monitoring the atmosphere dew point temperature.

Preferably, in the heating and/or soaking steps, the atmosphere comprises 0.1 to 10% by volume of H₂, the balance being an inert gas and unavoidable impurities.

The ferritic surface layer is formed by changing the microstructure of the steel due to the condition inside the annealing furnace, i.e. by decarburization and phase transformation. Indeed, the oxygen present in the annealing atmosphere react with the carbon from the steel to form gases such as CO₂ and CO, leading to a depletion of carbon atoms in the steel subsurface favoring the formation of ferrite. For example, a martensitic steel can transform into ferrite at conditions well known by the skilled in the art. Any means known to the skilled in the art can be used to form, on said substrate, the ferritic surface layer. Preferably, water injection is done during the annealing to form the desired ferritic surface layer.

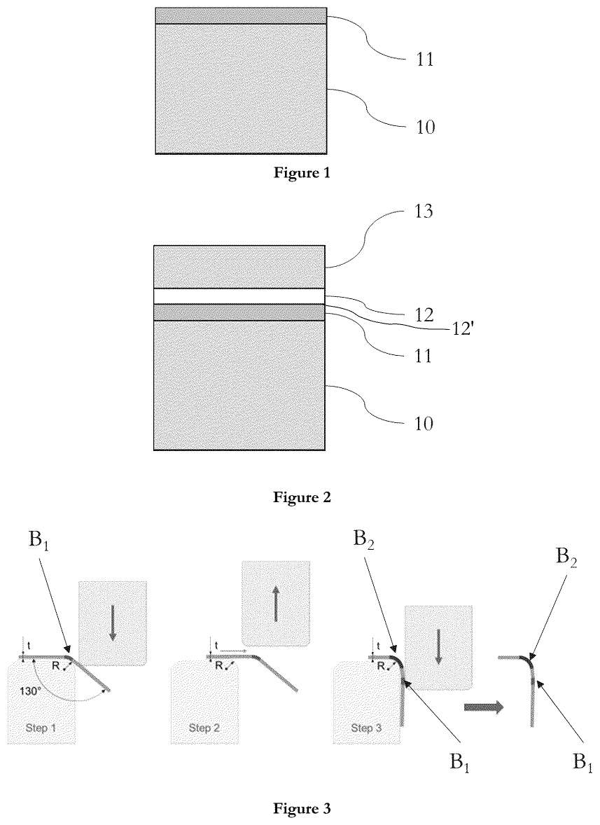

As illustrated in FIG. 1, the steel substrate exiting the annealing furnace comprises at least two layers: a steel bulk layer 10 and the ferritic surface layer 11 on top of said steel bulk 10. An iron oxide layer, from 5 to 15 nm, can be present on top of said ferritic layer.

In the coating step, the coating layer can be done by any possible means inside a vacuum chamber, e.g. any PVD processes. Preferably, the metallic coating layer is done by sputtering.

Preferably, the coating step comprises at least one coating process wherein at least a metallic vapour is ejected at a supersonic speed towards at least a side of said substrate to form a metallic coating.

The coating step can comprise one or several coating processes. For example, the coating step can comprise a PVD of a first metal alloy followed by a JVD of a second metal alloy wherein at least a metallic vapour is ejected at a supersonic speed towards at least a side of said substrate to form a metallic coating. Consequently, the metallic coating can comprise several layers of various metal or metal alloys.

The coating step can comprise a pre-treatment wherein an alkaline degreasing followed by a rinsing step can be performed.

For example, this process permits production of a coated strip as illustrated in FIG. 2. This coated strip comprises a steel bulk 10, a ferritic layer 11, a first metallic layer 12 and a second metallic layer 13.

An iron oxide layer, from 5 to 15 nm, can be present on top of the ferritic surface layer, between the ferritic layer 11 and the first metallic layer 12.

After studying the cause of the coating deterioration during forming operations, it has been found by the inventors that a lot of breakage happens inside the uppermost coating layer, e.g. inside the metallic coating.

Then, after determining that the breakage happens mostly in the uppermost coating layer, it has been found that the surface topography of the steel substrate had a great impact on the arising of coating deterioration. This is notably due to the fact that an uneven surface, comprising deep holes and crevices, impacts the surface affinity with rinsing waters of a pre-treatment section of a vacuum deposition process.

Thanks to the claimed process, the annealing conditions allows the formation of a ferritic layer by means of a decarburization of the steel bulk. The ferrite, being ductile, allows at least partially the clogging of the holes and crevices during the skin pass. Consequently, the presence of holes and crevices, or at least their severity, at the surface is reduced leading to a smaller amount of residual water on the steel substrate surface prior to the coating. Ultimately, a coated steel strip following this method is less prone to deteriorate, especially during its forming operation.

Preferably, said steel substrate is a strip or a band or a sheet.

Preferably, said steel substrate has a thickness from 0.5 mm to 5 mm. Even more preferably, said substrate has a thickness from 1 to 3 mm.

Preferably, said steel substrate has a composition comprising, in weight percent: 0.15<Si<0.4; 0.5<Mn<2.5; 0.1<C<0.4; P≤0.03; S≤0.02; 0.01≤Al≤0.1; Cu≤0.2; Ti+Nb≤0.20; Cr+Mo≤1 and a balance consisting of Fe and unavoidable impurities. Preferably, said steel substrate has a bulk microstructure comprising in surface fraction up to 10% of cumulated amounts of ferrite, austenite, bainite and carbide, and the balance being made of martensite. Even more preferably, said steel substrate has a bulk microstructure comprising in surface fraction up to 5% of cumulated amounts of ferrite, austenite, bainite and carbide, and the balance being made of martensite. Such a steel substrate is advantageous for automotive applications.

Those steels are known as martensitic steels.

Preferably, said steel substrate has a composition comprising, in weight percent: 0.15<Si<0.6; 0.17<Mn<2.3; 0.1<C<0.4; P≤0.05; S≤0.01; 0.015≤Al≤1.0; Cu≤0.2; B≤0.005; Ti+Nb≤0.15; Cr+Mo≤1.4 and a balance consisting of Fe and unavoidable impurities. Preferably, said steel substrate has a microstructure comprising in surface fraction up to 10% of austenite, ferrite and carbide, and the balance being made of bainite and martensite. Even more preferably, said steel substrate has a microstructure comprising in surface fraction up to 5% of cumulated amounts of ferrite, austenite and carbide, and the balance being made of bainite and martensite. Such a steel substrate is advantageous for automotive applications.

Those steels are known as dual-phase steels.

Preferably, in said annealing step, said substrate is maintained in a temperature range from 820° C. to 930° C.

Preferably, said ferritic layer has a microstructure comprising in surface fraction up to 5% of cumulated amounts of martensite, austenite, bainite and carbide, and the balance being made of ferrite.

Preferably, said ferritic layer has a thickness from 20 μm to 40 μm.

Preferably, said steel substrate is rolled at a reduction rate from 0.02% to 0.5%.

Preferably, in said coating step iii., said metallic coating comprises:

a first metallic layer comprising in weight at least 8% of nickel and at least 10% of chromium, the rest being iron and impurities resulting from the fabrication process, is formed on at least a side of said substrate by physical vapour deposition,

a second metallic layer, of at least one metal, is formed on said first metallic layer by means of jet vapour deposition.

Preferably, said second metallic layer is an anticorrosion metallic coating.

Preferably, in said coating step iii., said metallic coating comprises:

a first metallic layer, comprising Fe, Ni, Cr and Ti wherein the amount of Ti is ≥5 wt. % and wherein the following equation is satisfied: 8 wt. % <Cr+Ti<40 wt. %, the balance being Fe and Ni, is formed on at least a side of said substrate by physical vapour deposition,

a second metallic layer, of at least one metal, is formed on said first metallic layer by means of jet vapour deposition.

Preferably, said second metallic layer is an anticorrosion metallic coating.

Preferably, said first metallic layer is formed by sputtering.

For example, the first metallic layer can comprise, in weight percent: 0.02<C<0.2; 15<Cr<25; 5<Ni<22; Mo<3; 0.5<Si<1.5; 1.5<Mn<2.5; P<0.1; S<0.05 and a balance consisting of Fe and unavoidable impurities

For example, the first metallic layer can comprise, in weight percent: 0.02<C<0.5; 15<Cr<20; 9<Ni<15; 1.5<Mo<3; 0.5<Si<1.5; 1.5<Mn<2.5; P<0.1; S<0.05 and a balance consisting of Fe and unavoidable impurities.

Preferably, said second metallic layer comprises aluminum and magnesium or zinc or magnesium and zinc.

Preferably, said second metallic layer results from a coating process where at least a metallic vapour is ejected at a supersonic speed towards said substrate to form a metallic coating. Even more preferably, said second metallic layer results from a Jet Vapour Deposition process.

Preferably, said second metallic layer comprises in weight percent 0≤Mg<20 and 80<Zn≤100 and a balance consisting of unavoidable impurities. Even more preferably, said second metallic layer comprises in weight percent 0≤Mg<10 and 90<Zn≤100 and a balance consisting of unavoidable impurities.

Preferably, said second metallic layer is an anti-corrosion layer. Preferably, said second metallic layer comprises, in weight percent: 100% Zn. Preferably, said second metallic layer comprises, in weight percent: 0<Mg<10 and 90<Zn<100 and a balance consisting of unavoidable impurities.

Preferably, said second metallic layer comprises, in weight percent: 0<Mg<4 and 96<Zn<100 and a balance consisting of unavoidable impurities.

As illustrated in FIG. 2, the invention also relates to a coated steel strip comprising:
a steel bulk 10
a ferritic layer 11, on top of said steel bulk, having a thickness from 10 μm to 50 μm and a microstructure comprising in surface fraction up to 10% of cumulated amounts of martensite, austenite, bainite and carbide, and the balance being made of ferrite
an iron oxide layer 12′, on top of said ferritic layer, having a thickness from 5 to 15 nm,
a first metallic layer 12, on top of said iron oxide layer,
a second metallic layer 13, on top of said first metallic layer, having a thickness from 5 to 10 μm.

Preferably, said coated steel strip is manufactured according to a method as previously described wherein a first and a second metallic layers are coated.

Preferably, said coated steel strip has a thickness from 0.5 mm to 5 mm. Even more preferably, said coated steel strip has a from 1 to 3 mm.

One possibility is that said steel bulk 10 has a composition comprising, in weight percent: 0.15<Si<0.4; 0.5<Mn<2.5; 0.1<C<0.4; P≤0.03; S≤0.02; 0.01<Al≤0.1; Cu≤0.2; Ti+Nb≤0.20; C+Mo≤1 and a balance consisting of Fe and unavoidable impurities. Preferably, said steel substrate has a microstructure comprising in surface fraction up to 10% of ferrite, austenite, bainite and carbide, and the balance being made of martensite. Even more preferably, said steel substrate has a microstructure comprising in surface fraction up to 5% of ferrite, austenite, bainite and carbide, and the balance being made of martensite. Such a steel substrate is advantageous for automotive applications. Those steels are known as martensitic steels.

Another possibility is that said steel bulk 10 has a composition comprising, in weight percent: 0.15<Si<0.6; 0.17<Mn<2.3; 0.1<C<0.4; P≤0.05; S≤0.01; 0.015<Al≤1.0; Cu≤0.2; B≤0.005; Ti+Nb≤0.15; Cr+Mo≤1.4 and a balance consisting of Fe and unavoidable impurities and has a microstructure comprising in surface fraction up to 10% of austenite, ferrite and carbide, and the balance being made of bainite and martensite.

Preferably, said steel bulk that has strength greater than or equal to 450 MPa.

An iron oxide layer, from 5 to 10 nm, can be present on top of the ferritic surface layer.

Preferably, said ferritic layer has a microstructure comprising in surface fraction up to 5% of cumulated amounts of martensite, austenite, bainite and carbide, and the balance being made of ferrite.

Preferably, said ferritic layer has a thickness from 20 μm to 40 μm.

Preferably, said first metallic layer has a thickness from 2 to 15 nm.

Preferably, said first metallic layer comprises in weight at least 8% of nickel and at least 10% of chromium the rest being iron and impurities.

For example, the first metallic layer can comprise, in weight percent: 0.02<C<0.2; 15<Cr<25; 5<Ni<22; Mo<3; 0.5<Si<1.5; 1.5<Mn<2.5; P<0.1; S<0.05 and a balance consisting of Fe and unavoidable impurities

For example, the first metallic layer can comprise, in weight percent: 0.02<C<0.5; 15<Cr<20; 9<Ni<15; 1.5<Mo<3; 0.5<Si<1.5; 1.5<Mn<2.5; P<0.1; S<0.05 and a balance consisting of Fe and unavoidable impurities.

Preferably, said second metallic vapour is an anti-corrosion layer. Preferably, said second metallic vapour comprises, in weight percent: 100% Zn. Preferably, said second metallic vapour comprises, in weight percent: 0<Mg<3, 97<Zn<100 and a balance consisting of unavoidable impurities.

### EXPERIMENTAL TRIALS

The purpose of the experimental trials is to assess the effect of the claimed process on the coating breakage of a coated steel strip.

A first series of 5 samples of MS1500 steel sheet, having a thickness from 1.5 to 2.0 mm, of the type sold by ArcelorMittal under the brand MartINsite® 1500 was prepared. The exact composition of the steel used for the samples is: C 0.22%, Mn 1.8%, Si 0.26%, Cr 0.17%, Al 0.03%. The percentages are by weight, with the remainder being iron and potential impurities resulting from fabrication.

All the samples were subjected to the following steps.

An annealing step comprising a heating step and a soaking step.

The heating step has a temperature T₂ from 860° C. to 870° C. in an atmosphere comprising 5% by volume of H₂, the balance being N₂ and unavoidable impurities. The dew point of the heating step was either from −40° C. to −30° C. (dry annealing) or from −20° C. to −1° C. (wet annealing).

The soaking step has a temperature from 860° C. to 870° C. in an atmosphere comprising 5% by volume of H₂, the balance being N₂ and unavoidable impurities. The dew point of the soaking step was either from −40° C. to −30° C. (dry annealing) or from −20° C. to −1° C. (wet annealing).

Then, a skin pass at a reduction rate of 0.1% was performed for some samples (n°1, 3, 4, 5) whereas no skin pass was performed for one sample (n°2).

After the skin, a PVD of a first layer of 15 nm of metallic vapour of 0.02% C, 16-18% Cr, 10.5-13% Ni, 2-2.5% Mo, 1% Si, 2% Mn, 0.04% P, 0.03% S with the remainder being iron and potential impurities resulting from fabrication and a JVD of a second layer of 7.5 μm of Zn were performed.

Then, all the samples were tested by means of a 3-steps flanging test, as illustrated in FIG. 3.

In a first step, a sample having a thickness “t” is bent, to form an angle of 130°, on a given punch radius R at a first bending zone B₁. In the first series, all the samples had a ratio between the punch radius and the sample thickness of 2.5., i.e. R/t=2.5

Then in a second step, the sample is shifted to position the bender plumb from a second bending zone B₂.

In a third step, the strip is bent, to form an angle of 90°, at the second bending zone B₂, while the first bending zone B₁ is bent to become plane again.

This test permits to deform the coated steel strip in the first step and to compress the coated steel strip at the first bending zone in the third step due to the unbending of the first bend.

Ultimately, an adhesive is pressed against the first bending zone and depending on of the amount of matter sticking to the adhesive, the quality is classified into two categories: “OK” or “NOK”.

The characteristics of each specimen are presented in the table below.

TABLE 1

| Samples | | | Ferritic layer | |
|---|---|---|---|---|
| number | Annealing | Skin pass | thickness [μm] | Quality |
| 1 | dry | 0.1% | 1 | NOK |
| 2 | wet | 0% | 22 | NOK |
| 3 | wet | 0.1% | 16 | OK |
| 4 | wet | 0.1% | 21 | OK |
| 5 | wet | 0.1% | 31 | OK |

Samples 1 and 2 are not according to the invention. Samples 3 to 5 are according to the invention.

It is clear that when a steel sheet undergoes a process according to the invention, a good quality of the coating can be achieved. It is also clear that when at least one of the two steps preceding the coating step, e.g. the annealing or and skin-pass steps, is not done according to the invention, a good coating quality cannot be ensured reliably.

Consequently, only a method according to the present invention permits to reliably obtain a coating less prone to deteriorate, especially during its forming operation.

What is claimed is:

1-14. (canceled)

15. A method for depositing metallic coatings on a steel substrate, the method comprising:
i. an annealing step, in an annealing furnace, including
a. a pre-heating wherein the steel substrate is heated to a temperature T1 lower than 600° C.
b. a heating step wherein the steel substrate is heated from T1 to a recrystallisation temperature T2 from 720° C. to 1000° C. in an atmosphere comprising 0.1 to 90% by volume of H₂, a balance being an inert gas and unavoidable impurities and having a dew point from −25° C. to 10° C. and then
c. a soaking step wherein the steel substrate is maintained in a temperature range from 720° C. to 1000° C. in an atmosphere comprising 0.1 to 90% by volume of H₂, a balance being the inert gas or a further inert gas and unavoidable impurities and having a dew point from −25° C. to 10° C.,
wherein such an annealing step allows formation, on the steel substrate, of a ferritic surface layer having a thickness from 10 μm to 50 μm and a microstructure comprising in surface fraction up to 10% of cumulated amounts of martensite, austenite, bainite and carbide, and the balance being made of ferrite,
ii. a skin pass step, at a temper mill, wherein the steel substrate is rolled with a reduction from 0.02% to 2%,
iii. a coating step, inside a vacuum chamber, wherein at least a metallic vapour is ejected towards at least a side of the steel substrate to form a metallic coating.

16. The method as recited in claim 15 wherein the steel substrate has a thickness from 0.5 mm to 5 mm.

17. The method as recited in claim 15 wherein the steel substrate has a composition comprising, in weight percent: 0.15<Si<0.4; 0.5<Mn<2.5; 0.1<C<0.4; P≤0.03; S≤0.02; 0.01<Al≤0.1; Cu≤0.2; Ti+Nb≤0.20; Cr+Mo≤1 and a balance consisting of Fe and unavoidable impurities.

18. The method as recited in claim 17 wherein the steel substrate has a bulk microstructure comprising in surface fraction up to 10% of cumulated amounts of ferrite, austenite, bainite and carbide, and the balance being made of martensite.

19. The method as recited in claim 15 wherein the steel substrate has a composition comprising, in weight percent: 0.15<Si<0.6; 0.17<Mn<2.3; 0.1<C<0.4; P≤0.05; S≤0.01; 0.015<Al≤1.0; Cu≤0.2; B≤0.005; Ti+Nb≤0.15; Cr+Mo≤1.4 and a balance consisting of Fe and unavoidable impurities.

20. The method as recited in claim 19 wherein the steel substrate has a bulk microstructure comprising in surface fraction up to 5% of ferrite and the balance being made of martensite and bainite.

21. The method as recited in claim 15 wherein in the annealing step, the steel substrate is maintained in a temperature range from 820° C. to 930° C.

22. The method as recited in claim 15 wherein the ferritic layer has a microstructure comprising in surface fraction up to 5% of cumulated amounts of martensite, austenite, bainite and carbide, and the balance being made of ferrite.

23. The method as recited in claim 15 wherein the ferritic layer has a thickness from 20 μm to 40 μm.

24. The method as recited in claim 15 wherein in the coating step,
a first metallic layer comprising in weight at least 8% of nickel and at least 10% of chromium, a rest being iron and impurities resulting from the fabrication process, is formed on at least a side of the substrate by physical vapour deposition, and
a second metallic vapour is ejected towards at least said side of said substrate to form a layer of at least one metal on said first metallic layer.

25. The method as recited in claim 15 wherein the second metallic vapour is an anti-corrosion layer.

26. The method as recited in claim 15 wherein in the coating step, the surface layer is formed by JVD.

27. A coated steel strip comprising:
a steel bulk;
a ferritic layer, on top of the steel bulk, having a thickness from 10 μm to 50 μm and a microstructure comprising in surface fraction up to 10% of cumulated amounts of martensite, austenite, bainite and carbide, and a balance being made of ferrite;
an iron oxide layer, on top of said ferritic layer, having a thickness from 5 to 15 nm;
a first metallic layer, on top of the steel oxide layer; and
a second metallic layer, on top of the first metallic layer, having a thickness from 5 to 10 μm.

28. A coated steel strip produced according to the method as recited in claim 24.
